(19) United States
(12) Patent Application Publication
(10) Pub. No.: US 2026/0105974 A1
(43) Pub. Date: Apr. 16, 2026

(54) CORRECTIVE READ TECHNIQUES FOR MEMORY SYSTEMS

(71) Applicant: Micron Technology, Inc., Boise, ID (US)

(72) Inventors: Amiya Banerjee, Bangalore (IN); Pranav Tharanath, Bangalore (IN); Akil M, Bangalore (IN); Sriraman Sridharan, Hosur (IN)

(21) Appl. No.: 19/342,169

(22) Filed: Sep. 26, 2025

Related U.S. Application Data
(60) Provisional application No. 63/705,968, filed on Oct. 10, 2024.

(51) Int. Cl. G11C 16/26; G11C 16/08; G11C 16/30

(52) U.S. Cl. CPC G11C 16/26; G11C 16/08; G11C 16/30

(57) ABSTRACT

Methods, systems, and devices for corrective read techniques for memory systems are described. A memory system may determine respective ranges of stored charge for each first memory cell of a set of first memory cells associated with a first word line. The ranges of stored charge may correspond to respective written states of each first memory cell. The memory system may read a set of second memory cells associated with a second word line based on biasing each second memory cell of the plurality of second memory cells with a respective set of one or more read voltages. The one or more read voltages may be based on the respective ranges of stored charge of the first memory cells. The memory system may output data associated with the second word line based on the reading of the plurality of second memory cells.

### CROSS REFERENCE

The present Application for Patent claims priority to U.S. Patent Application No. 63/705,968 by Banerjee et al., entitled “CORRECTIVE READ TECHNIQUES FOR MEMORY SYSTEMS,” filed Oct. 10, 2024, which is assigned to the assignee hereof, and which is expressly incorporated by reference in its entirety herein.

### TECHNICAL FIELD

The following relates to one or more systems for memory, including corrective read techniques for memory systems.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not- or (NOR) and not- and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 shows an example of a system that supports corrective read techniques for memory systems in accordance with examples as disclosed herein.

FIG. 2 shows an example of a memory architecture that supports corrective read techniques for memory systems in accordance with examples as disclosed herein.

FIG. 3 shows an example of threshold voltage distributions that support corrective read techniques for memory systems in accordance with examples as disclosed herein.

FIG. 4 shows an example of a timing diagram that supports corrective read techniques for memory systems in accordance with examples as disclosed herein.

FIG. 5 shows a block diagram of a memory system that supports corrective read techniques for memory systems in accordance with examples as disclosed herein.

FIG. 6 shows a flowchart illustrating a method or methods that support corrective read techniques for memory systems in accordance with examples as disclosed herein.

### DETAILED DESCRIPTION

Memory cells of a memory system (e.g., a not-AND (NAND) memory system, a quad-level cell (QLC) memory device, a triple-level cell (TLC) memory device, a multi-level cell (MLC) memory device) may experience charge migration effects (e.g., lateral charge migration) in which electrical charge from one memory cell leaks into one or more adjacent (e.g., neighboring) memory cells (e.g., leakage through a charge storing layer). Charge migration may affect a stored charge state (e.g., cause a shift in threshold voltage) of a memory cell, which may result in data errors (e.g., bit errors) during a read operation of the memory cell. Some memory cells (e.g., QLCs) may have a relatively low read window budget (RWB), which may be associated with supporting storage of multiple bits per cell (e.g., one of 16 charge states for a QLC), and which may be relatively more-susceptible to errors caused by charge migration. In some cases, corrective reading techniques may be used to adjust read voltages and improve RWB, which may compensate for at least some aspects of charge migration, among other adverse storage behaviors. However, corrective read operations may increase resource usage and adversely impact read performance. For instance, corrective read operations may perform multiple voltage strobing operations (e.g., for sensing a stored charge range or threshold voltage range of a memory cell) to one or more word lines in order to adjust one or more read voltages, which may increase latency of the read operation and degrade user experience.

In accordance with one or more techniques described herein, a memory system may be configured to perform corrective read operations with reduced strobe operations and reduced latency. During a read operation of a first word line, for example, the memory system may perform one or more strobing operations that are used to categorize each memory cell coupled with the first word line (e.g., at least one logical page of the memory cell) into a range of stored charge, which may be referred to as a “bin.” Each bin may correspond to a respective range of stored charge, which also may be associated with a respective range of threshold voltages, and each memory cell may be categorized into a particular bin based on a written state (e.g., a charge state, a threshold voltage state) of the memory cell. In some examples, the categorization may be performed concurrently with the read operation (e.g., to also read data from memory cells coupled with the word line), and the memory system may store (e.g., to one or more internal latches, to one or more caches) information associated with the range of stored charge (e.g., an identifier, a bit value) for each memory cell coupled with the first word line. During a subsequent read operation for a second word line (e.g., an adjacent word line, as part of a sequential read operation), the memory system may adjust read voltage offsets for reading memory cells coupled with the second word line based on the categorization (e.g., the binning) of the memory cells coupled with the first word line. Accordingly, the memory system may counteract the charge migration effects between memory cells while reducing processing overhead, thus improving the accuracy of the read operation and maintaining or reducing latency.

In addition to applicability in memory systems as described herein, corrective read techniques for memory systems may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by improving memory access speeds and reducing overhead associated with memory access operations (e.g., for corrective read operations, to overcome read errors associated with charge migration or other degradation of a stored state), which may decrease processing or latency times, improve response times, and otherwise improve user experience, among other benefits.

Features of the disclosure are illustrated and described in the context of systems, devices, and circuits. Features of the disclosure are further illustrated and described in the context of voltage distributions, timing diagrams, and flowcharts.

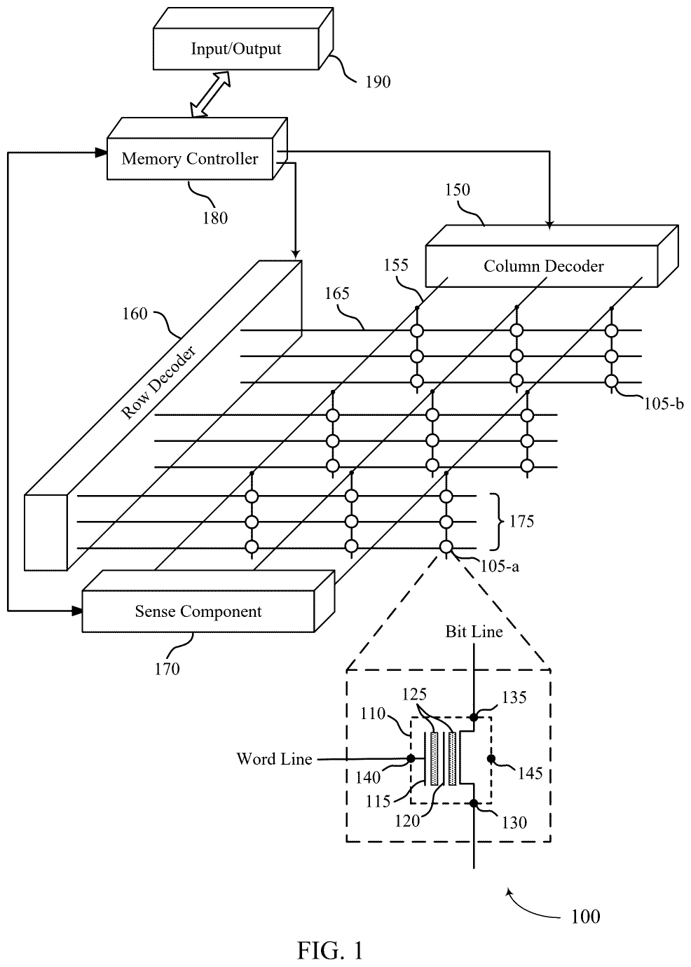

FIG. 1 shows an example of a memory device 100 that supports corrective read techniques for memory systems in accordance with examples as disclosed herein. FIG. 1 is an illustrative representation of various components and features of the memory device 100. As such, the components and features of the memory device 100 are shown to illustrate functional interrelationships, and not necessarily physical positions within the memory device 100. Further, although some elements included in FIG. 1 are labeled with a numeric indicator, some other corresponding elements are not labeled, even though they are the same or would be understood to be similar, in an effort to increase visibility and clarity of the depicted features. In various examples, a memory device 100 may be referred to as or be an example of a memory system, or a memory system may include one or more memory devices 100 (e.g., in a managed NAND (mNAND) implementation, in which at least some operations of the one or more memory devices 100 may be performed, initiated, supported by, or coordinated by a memory system controller of the memory system that is coupled with the one or more memory devices).

The memory device 100 may include one or more memory cells 105, such as memory cell 105-a and memory cell 105-b. In some examples, a memory cell 105 may be a NAND memory cell, such as in the blow-up diagram of memory cell 105-a. Each memory cell 105 may be programmed to store a logic value representing one or more bits of information. In some examples, a single memory cell 105—such as a memory cell 105 configured as a single-level cell (SLC)—may be programmed to one of two supported states and thus may store one bit of information at a time (e.g., a logic 0 or a logic 1). In some other examples, a single memory cell 105—such a memory cell 105 configured as an MLC, a TLC, a QLC, or other type of multiple-level memory cell 105—may be programmed to one state of more than two supported states and thus may store more than one bit of information at a time. In some cases, a multiple-level memory cell 105 (e.g., an MLC memory cell, a TLC memory cell, a QLC memory cell) may be physically different than an SLC cell. For example, a multiple-level memory cell 105 may use a different cell geometry or may be fabricated using different materials. In some examples, a multiple-level memory cell 105 may be physically the same or similar to an SLC cell, and other circuitry in a memory block (e.g., a controller, sense amplifiers, drivers) may be configured to operate (e.g., read and program) the memory cell as an SLC cell, or as an MLC cell, or as a TLC cell, etc.

In some NAND memory arrays, each memory cell 105 may be illustrated as a transistor that includes a charge trapping structure (e.g., a floating gate, a replacement gate, a dielectric material) for storing an amount of charge representative of a logic value. For example, the blow-up in FIG. 1 illustrates a NAND memory cell 105-a that includes a transistor 110 (e.g., a metal-oxide-semiconductor (MOS) transistor) that may be used to store a logic value. The transistor 110 may include a control gate 115 and a charge trapping structure 120 (e.g., a floating gate, a replacement gate), where the charge trapping structure 120 may, in some examples, be between two portions of dielectric material 125. The transistor 110 also may include a first node 130 (e.g., a source or drain) and a second node 135 (e.g., a drain or source). A logic value may be stored in transistor 110 by storing (e.g., writing) a quantity of electrons (e.g., an amount of charge) on the charge trapping structure 120. An amount of charge to be stored on the charge trapping structure 120 may depend on the logic value to be stored. The charge stored on the charge trapping structure 120 may affect the threshold voltage of the transistor 110, thereby affecting the amount of current that flows through the transistor 110 when the transistor 110 is activated (e.g., when a voltage is applied to the control gate 115, when the memory cell 105-a is read). In some examples, the charge trapping structure 120 may be an example of a floating gate or a replacement gate that may be part of a 2D NAND structure. For example, a 2D NAND array may include multiple control gates 115 and charge trapping structures 120 arranged around a single channel (e.g., a horizontal channel, a vertical channel, a columnar channel, a pillar channel).

A logic value stored in the transistor 110 may be sensed (e.g., as part of a read operation) by applying a voltage to the control gate 115 (e.g., to control node 140, via a word line 165) to activate the transistor 110 and measuring (e.g., detecting, sensing) an amount of current that flows through the first node 130 or the second node 135 (e.g., via a bit line 155). For example, a sense component 170 may determine whether an SLC memory cell 105 stores a logic 0 or a logic 1 in a binary manner (e.g., based on a presence or absence of a current through the memory cell 105 when a read voltage is applied to the control gate 115, based on whether the current is above or below a threshold current). For a multiple-level memory cell 105, a sense component 170 may determine a logic value stored in the memory cell 105 based on various intermediate threshold levels of current when a read voltage is applied to the control gate 115, or by applying different read voltages to the control gate and evaluating different resulting levels of current through the transistor 110, or various combinations thereof. In one example of a multiple-level architecture, a sense component 170 may determine the logic value of a TLC memory cell 105 based on eight different levels of current, or ranges of current, that define the eight potential logic values that could be stored by the TLC memory cell 105.

An SLC memory cell 105 may be written by applying one of two voltages (e.g., a voltage above a threshold or a voltage below a threshold) to the memory cell 105 to store, or not store, an electric charge on the charge trapping structure 120 and thereby cause the memory cell 105 to store one of two possible logic values. For example, when a first voltage is applied to the control node 140 (e.g., via a word line 165) relative to a bulk node 145 (e.g., a body node) for the transistor 110 (e.g., when the control node 140 is at a higher voltage than the bulk), electrons may tunnel into the charge trapping structure 120. Injection of electrons into the charge trapping structure 120 may be referred to as programming the memory cell 105 and may occur as part of a write operation. A programmed memory cell may, in some cases, be considered as storing a logic 0. When a second voltage is applied to the control node 140 (e.g., via the word line 165) relative to the bulk node 145 for the transistor 110 (e.g., when the control node 140 is at a lower voltage than the bulk node 145), electrons may leave the charge trapping structure 120. Removal of electrons from the charge trapping structure 120 may be referred to as erasing the memory cell 105 and may occur as part of an erase operation. An erased memory cell may, in some cases, be considered as storing a logic 1. In some cases, memory cells 105 may be programmed at a page level of granularity due to memory cells 105 of a page sharing a common word line 165, and memory cells 105 may be erased at a block level of granularity due to memory cells 105 of a block sharing commonly biased bulk nodes 145.

In contrast to writing an SLC memory cell 105, writing a multiple-level (e.g., MLC, TLC, or QLC) memory cell 105 may involve applying different voltages to the memory cell 105 (e.g., to the control node 140 or bulk node 145 thereof) at a finer level of granularity to more finely control the amount of charge stored on the charge trapping structure 120, thereby enabling a larger set of logic values to be represented. Thus, multiple-level memory cells 105 may provide greater density of storage relative to SLC memory cells 105 but may, in some cases, involve narrower read or write margins or greater complexities for supporting circuitry.

A charge-trapping NAND memory cell 105 may operate similarly to a floating-gate NAND memory cell 105 but, instead of or in addition to storing a charge on a charge trapping structure 120, a charge-trapping NAND memory cell 105 may store a charge representing a logic state in a dielectric material between the control gate 115 and a channel (e.g., a channel between a first node 130 and a second node 135). Thus, a charge-trapping NAND memory cell 105 may include a charge trapping structure 120, or may implement charge trapping functionality in one or more portions of dielectric material 125, among other configurations.

In some examples, each page of memory cells 105 may be connected to a corresponding word line 165, and each column of memory cells 105 may be connected to a corresponding bit line 155 (e.g., digit line). Thus, one memory cell 105 may be located at the intersection of a word line 165 and a bit line 155. This intersection may be referred to as an address of a memory cell 105. In some cases, word lines 165 and bit lines 155 may be substantially perpendicular to one another, and may be generically referred to as access lines or select lines.

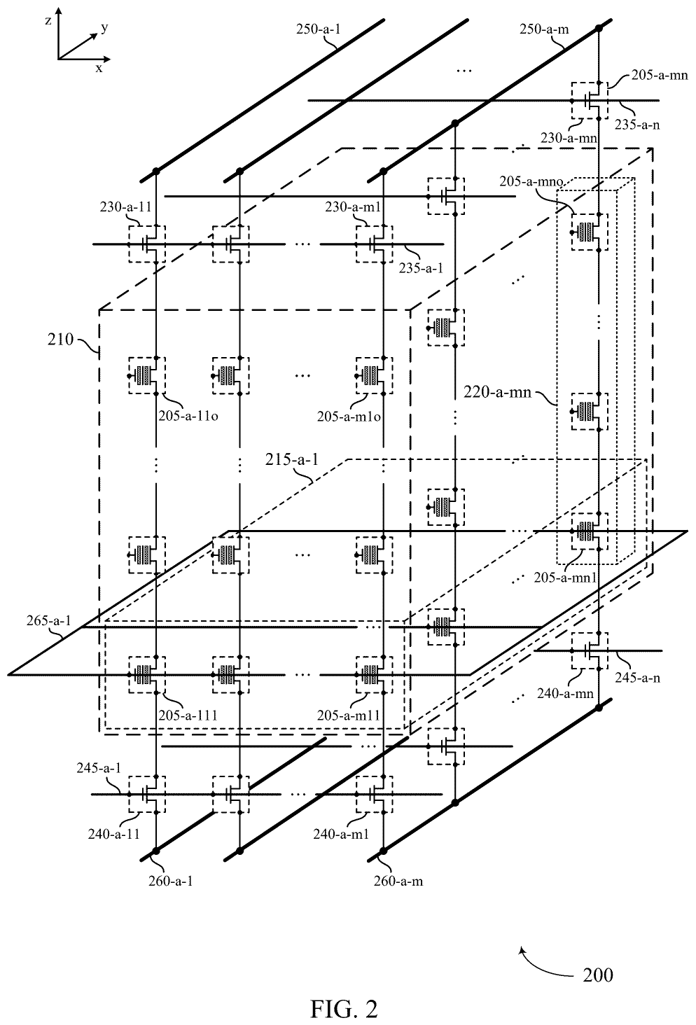

In some cases, a memory device 100 may include a three-dimensional (3D) memory array, where multiple two-dimensional (2D) memory arrays may be formed on top of one another. In some examples, such an arrangement may increase the quantity of memory cells 105 that may be fabricated on a single die or substrate as compared with 1D arrays, which, in turn, may reduce production costs, or increase the performance of the memory array, or both. In the example of FIG. 1, memory device 100 includes multiple levels (e.g., decks, layers, planes, tiers) of memory cells 105. The levels may, in some examples, be separated by an electrically insulating material. Each level may be aligned or positioned so that memory cells 105 may be aligned (e.g., exactly aligned, overlapping, or approximately aligned) with one another across each level, forming a memory cell stack 175. In some cases, memory cells aligned along a memory cell stack 175 may be referred to as a string of memory cells 105 (e.g., as described with reference to FIG. 2).

Accessing memory cells 105 may be controlled through a row decoder 160 and a column decoder 150. For example, the row decoder 160 may receive a row address from the memory controller 180 and activate an appropriate word line 165 based on the received row address. Similarly, the column decoder 150 may receive a column address from the memory controller 180 and activate an appropriate bit line 155. Thus, by activating one word line 165 and one bit line 155, one memory cell 105 may be accessed. As part of such accessing, a memory cell 105 may be read (e.g., sensed) by sense component 170. For example, the sense component 170 may be configured to determine the stored logic value of a memory cell 105 based on a signal generated by accessing the memory cell 105. The signal may include a current, a voltage, or both a current and a voltage on the bit line 155 for the memory cell 105 and may depend on the logic value stored by the memory cell 105. The sense component 170 may include various circuitry (e.g., transistors, amplifiers) configured to detect and amplify a signal (e.g., a current or voltage) on a bit line 155. The logic value of memory cell 105 as detected by the sense component 170 may be output via input/output component 190. In some cases, a sense component 170 may be a part of a column decoder 150 or a row decoder 160, or a sense component 170 may otherwise be connected to or in electronic communication with a column decoder 150 or a row decoder 160.

A memory cell 105 may be programmed or written by activating the relevant word line 165 and bit line 155 to enable a logic value (e.g., representing one or more bits of information) to be stored in the memory cell 105. A column decoder 150 or a row decoder 160 may accept data (e.g., from the input/output component 190) to be written to the memory cells 105. In the case of NAND memory, a memory cell 105 may be written by storing electrons in a charge trapping structure or an insulating layer.

A memory controller 180 may control the operation (e.g., read, write, re-write, refresh) of memory cells 105 through the various components (e.g., row decoder 160, column decoder 150, sense component 170). In some cases, one or more of a row decoder 160, a column decoder 150, and a sense component 170 may be co-located with a memory controller 180. A memory controller 180 may generate row and column address signals in order to activate a desired word line 165 and bit line 155. In some examples, a memory controller 180 may generate and control various voltages or currents used during the operation of memory device 100.

Memory cells 105 may experience charge migration effects (e.g., lateral charge migration) in which electrical charge from one memory cell 105 leaks into one or more adjacent (e.g., neighboring) memory cells 105 (e.g., leakage from one charge trapping structure 120 of a memory cell to another). Charge migration may affect a charge state (e.g., data state, voltage state, an amount of charge stored in a given charge-trapping structure 120) of a memory cell 105, which may result in errors when attempting to read the data stored at the memory cell 105. In some cases, corrective reading techniques may be used to adjust read voltages and improve RWB. However, corrective read operations may adversely impact read performance based on voltage strobing operations to adjacent word lines 165 in order to adjust one or more read voltages, which may increase latency of the read operation and degrade operating efficiency of a memory device 100.

In accordance with one or more techniques described herein, a memory device 100 may be configured to perform corrective read operations with reduced strobe operations and reduced latency. During a read operation of a first word line 165, for example, the memory device 100 may perform one or more strobing operations that are used to categorize each memory cell 105 coupled the first word line 165 into a range of stored charge (e.g., a bin) based on a written state (e.g., a charge state, a voltage state) of the memory cell 105. The memory device 100 may store (e.g., to one or more internal latches or caches of the memory device 100, which may be included in a memory controller 180 or an input/output component 190) information associated with the range of stored charge (e.g., an identifier, a bit value) for each memory cell 105 of the first word line 165. During a subsequent operation for a second word line 165 (e.g., a sequential word line 165, a next word line 165), the memory device 100 may adjust read voltage offsets for reading memory cells 105 coupled with the second word line 165 based on the categorization (e.g., the binning) of the memory cells 105 coupled with the first word line 165. Accordingly, the memory device 100 may counteract the charge migration effects while reducing processing overhead, thus improving the accuracy of the read operation and maintaining or reducing latency of the memory device 100.

FIG. 2 shows an example of a memory architecture 200 that supports corrective read techniques for memory systems in accordance with examples as disclosed herein. The memory architecture 200 may be an example of a portion of a memory device (e.g., a portion of a memory system), such as a memory device 100. Although some elements of a set of elements (e.g., an array of elements) are included in FIG. 2, some elements may be omitted for the sake of visibility and clarity of the depicted elements. Moreover, although some elements included in FIG. 2 are labeled with reference numbers, some other corresponding elements are not labeled, though they would be understood by a person having ordinary skill in the art to be the same as or similar to the labeled elements. Aspects of the memory architecture 200 may be described with reference to an x-direction, a y-direction, and a z-direction of the illustrated coordinate system.

The memory architecture 200 includes a three-dimensional array of memory cells 205, which may be examples of memory cells 105 described with reference to FIG. 1 (e.g., transistors 110, NAND memory cells). In some examples, the memory cells 205 may be connected in a 3D NAND configuration. For example, the memory cells 205 may be included in a block 210, which may be arranged as a 3D array of m memory cells along the x-direction, n memory cells along the y-direction, and o memory cells along the z-direction. Each memory cell 205 may be located (e.g., addressed) in accordance with an index i along the x-direction, an index j along the y-direction, and an index k along the z-direction (e.g., for locating a memory cell 205-a-ijk). A memory device 100 may include any quantity of one or more blocks 210 in accordance with examples as disclosed herein, and different blocks 210 may be adjacent along the x-direction, along the y-direction, or along the z-direction, or any combination thereof.

In the example of memory architecture 200, the block 210 may be divided into a set of pages 215 (e.g., a quantity of o pages 215) along the z-direction, including a page 215-a-1 associated with memory cells 205-a-111 through 205-a-mn1. In some examples, each page 215 may be associated with the same word line 265, (e.g., a word line 165 described with reference to FIG. 1), which may be coupled with a control gate 115 of each of the memory cells 205 of the page 215. For example, page 215-a-1 may be associated with a word line 265-a-1, and other pages 215-a-i may be associated with a different respective word line 265-a-i (not shown). In some examples, a word line 265 in accordance with the memory architecture 200 may be implemented as planar conductor (e.g., in an xy-plane) that is coupled with each of the memory cells 205 of the page 215.

In the example of memory architecture 200, the block 210 also may be divided into a set of strings 220 (e.g., a quantity of (m×n) strings 220) in an xy-plane, including a string 220-a-mn associated with memory cells 205-a-mnl through 205-a-mno. In some examples, each string 220 may include a set of memory cells 205 connected in series (e.g., along the z-direction, in which a drain of one memory cell 205 in the string 220 may be coupled with a source of another memory cell 205 in the string 220). In some examples, memory cells 205 of a string 220 may be implemented along a common channel, such as a pillar channel (e.g., a columnar channel, a pillar of doped semiconductor) along the z-direction. Each memory cell 205 in a string 220 may be associated with a different word line 265, such that a quantity of word lines 265 in the memory architecture 200 may be equal to the quantity of memory cells 205 in a string 220. Accordingly, a string 220 may include memory cells 205 from multiple pages 215, and a page 215 may include memory cells 205 from multiple strings 220.

In some examples, memory cells 205 may be programmed (e.g., set to a logic 0 value) and read from in accordance with a granularity, such as at the granularity of a page 215 or portion thereof, but may not be erasable (e.g., reset to a logic 1 value) in accordance with the granularity, such as the granularity of a page 215 or portion thereof. For example, NAND memory may instead be erasable in accordance with a different (e.g., higher) level of granularity, such as at the level of granularity the block 210. In some cases, a memory cell 205 may be erased before it may be re-programmed. Different memory devices may have different read, write, or erase characteristics.

In some examples, each string 220 of a block 210 may be coupled with a respective transistor 230 (e.g., a string select transistor, a drain select transistor) at one end of the string 220 (e.g., along the z-direction) and a respective transistor 240 (e.g., a source select transistor, a ground select transistor) at the other end of the string 220. In some examples, a drain of each transistor 230 may be coupled with a bit line 250 of a set of bit lines 250 associated with the block 210, where the bit lines 250 may be examples of bit lines 155 described with reference to FIG. 1. A gate of each transistor 230 may be coupled with a select line 235 (e.g., a string select line, a drain select line). Thus, a transistor 230 may be used to couple a string 220 with a bit line 250 based on applying a voltage to the select line 235, and thus to the gate of the transistor 230. Although illustrated as separate lines along the x-direction, in some examples, select lines 235 may be common to all the transistors 230 associated with the block 210 (e.g., a commonly biased string select node). For example, like the word lines 265 of the block 210, select lines 235 associated with the block 210 may, in some examples, be implemented as a planar conductor (e.g., in an xy-plane) that is coupled with each of the transistors 230 associated with the block 210.

In some examples, a source of each transistor 240 associated with the block 210 may be coupled with a source line 260 of a set of source lines 260 associated with the block 210. In some examples, the set of source lines 260 may be associated with a common source node (e.g., a ground node) corresponding to the block 210. A gate of each transistor 240 may be coupled with a select line 245 (e.g., a source select line, a ground select line). Thus, a transistor 240 may be used to couple a string 220 with a source line 260 based on applying a voltage to the select line 245, and thus to the gate of the transistor 240. Although illustrated as separate lines along the x-direction, in some examples, select lines 245 also may be common to all the transistors 240 associated with the block 210 (e.g., a commonly biased ground select node). For example, like the word lines 265 of the block 210, select lines 245 associated with the block 210 may, in some examples, be implemented as a planar conductor (e.g., in an xy-plane) that is coupled with each of the transistors 240 associated with the block 210.

To operate the memory architecture 200 (e.g., to perform a program operation, a read operation, or an erase operation on one or more memory cells 205 of the block 210), various voltages may be applied to one or more select lines 235 (e.g., to the gate of the transistors 230), to one or more bit lines 250 (e.g., to the drain of one or more transistors 230), to one or more word lines 265, to one or more select lines 245 (e.g., to the gate of the transistors 240), to one or more source lines 260 (e.g., to the source of the transistors 240), or to a bulk for the memory cells 205 (not shown) of the block 210. In some cases, each memory cell 205 of a block 210 may have a common bulk, the voltage of which may be controlled independently of bulks for other blocks 210.

In some cases, as part of a read operation for a memory cell 205, a positive voltage may be applied to the corresponding bit line 250 while the corresponding source line 260 may be grounded or otherwise biased at a voltage lower than the voltage applied to the bit line 250. In some examples, voltages may be concurrently applied to the select line 235 and the select line 245 that are above the threshold voltages of the transistor 230 and the transistor 240, respectively, for the memory cell 205, thereby activating the transistor 230 and transistor 240 such that a channel associated with the string 220 that includes the memory cell 205 (e.g., a pillar channel) may be electrically connected with (e.g., electrically connected between) the corresponding bit line 250 and source line 260. A channel may be an electrical path through the memory cells 205 in the string 220 (e.g., through the sources and drains of the transistors in the memory cells 205 of the string 220) that may conduct current under some operating conditions.

In some examples, multiple word lines 265 (e.g., in some cases all word lines 265) of the block 210—except a word line 265 associated with a page 215 of the memory cell 205 to be read—may concurrently be set to a voltage (e.g., VREAD) that is higher than the threshold voltage (VT) of the memory cells 205. VREAD may cause all memory cells 205 in the unselected pages 215 be activated so that each unselected memory cell 205 in the string 220 may maintain high conductivity within the channel. In some examples, the word line 265 associated with the memory cell 205 to be read may be set to a voltage, VTarget. Where the memory cells 205 are operated as SLC memory cells, VTarget may be a voltage that is between (i) VT of a memory cell 205 in an erased state and (ii) VT of a memory cell 205 in a programmed state.

When the memory cell 205 to be read exhibits an erased VT (e.g., VTarget>VT of the memory cell 205), the memory cell 205 may turn “ON” in response to the application of VTarget to the word line 265 of the selected page 215, which may allow a current to flow in the channel of the string 220, and thus from the bit line 250 to the source line 260. When the memory cell 205 to be read exhibits a programmed VT (e.g., VTarget<VT of the selected memory cell), the memory cell 205 may remain “OFF” despite the application of VTarget to the word line 265 of the selected page 215, and thus may prevent a current from flowing in the channel of the string 220, and thus from the bit line 250 to the source line 260.

A signal on the bit line 250 for the memory cell 205 (e.g., an amount of current below or above a threshold) may be sensed (e.g., by a sense component 170 as described with reference to FIG. 1), and may indicate whether the memory cell 205 became conductive or remained non-conductive in response to the application of VTarget to the word line 265 of the selected page 215. The sensed signal thus may be indicative of whether the memory cell 205 was in an erased state (e.g., storing a logic 1) or a programmed state (e.g., storing a logic 0). Though aspects of the example read operation above have been explained in the context of an SLC memory cell 205 for clarity, such techniques may be extended or altered and applied in the context of a multiple-level memory cell 205 (e.g., through the use of multiple values of VTarget corresponding to the different amounts of charge that may be stored in one multiple-level memory cell 205).

In some cases, as part of a program operation for a memory cell 205, charge may be added to a portion of the memory cell 205 such that current flow through the memory cell 205, and thus the corresponding string 220, may be inhibited when the memory cell 205 is later read. For example, charge may be injected into a charge trapping structure 120 as shown in memory cell 105-a of FIG. 1. In some cases, respective voltages may be applied to the word line 265 of the page 215 and the bulk of the memory cell 205 to be programmed such that a control gate 115 of the memory cell 205 is at a higher voltage than the bulk of the memory cell 205 (e.g., a positive voltage may be applied to the word line). Concurrently, voltages may be applied to the select line 235 and the select line 245 that are above the threshold voltages of the transistor 230 and the transistor 240, respectively, thereby activating the transistor 230 and the transistor 240, and the bit line 250 for the memory cell 205 to be programmed may be set to a relatively high voltage. This may cause an electric field such that electrons are pulled from the source of the memory cell 205 towards the drain. The electric field may also cause some of these electrons to be pulled through dielectric material 125 and thereby injected into the charge trapping structure 120 of the memory cell 205, through a process which may in some cases be referred to as tunnel injection.

In some cases, a single program operation may program some or all memory cells 205 in a page 215, as the memory cells 205 of the page 215 may all share a common word line 265 and a common bulk. For a memory cell 205 of the page 215 for which it is not desired to write a logic 0 (e.g., not desired to program the memory cell 205), the corresponding bit line 250 may be set to a relatively low voltage (e.g., ground), which may inhibit the injection of electrons into a charge trapping structure 120. Though aspects of the example program operation above have been explained in the context of an SLC memory cell 205 for clarity, such techniques may be extended and applied to the context of a multiple-level memory cell 205 (e.g., through the use of multiple programming voltages applied to the word line 265, or multiple passes or pulses of a programming voltage applied to the word line 265, corresponding to the different amounts of charge that may be stored in one multiple-level memory cell 205).

In some cases, as part of an erase operation for a memory cell 205, charge may be removed from a portion of the memory cell 205 such that current flow through the memory cell 205, and thus the corresponding string 220, may be uninhibited (e.g., allowed, at least to a greater extent) when the memory cell 205 is later read. For example, charge may be removed from a charge trapping structure 120 as shown in memory cell 105-a of FIG. 1. In some cases, respective voltages may be applied to the word line 265 of the page 215 and the bulk of the memory cell 205 to be erased such that a control gate 115 of the memory cell 205 is at a lower voltage than the bulk of the memory cell 205 (e.g., a positive voltage may be applied to the bulk), which may cause an electric field that pulls electrons out of the charge trapping structure 120 and into the bulk of the memory cell 205. In some cases, a single program operation may erase all memory cells 205 in a block 210, as the memory cells 205 of the block 210 may all share a common bulk.

Memory cells 205 may experience charge migration effects in which electrical charge from one memory cell 205 leaks into one or more adjacent memory cells 205 (e.g., along the z-direction, from one charge trapping structure 120 to another, from one memory cell 205 to an adjacent memory cell 205 in a given string 220, along a charge trapping material that may be contiguous along the z-direction from one memory cell 205 in one page 215 to another memory cell 205 in another page 215). Charge migration may affect a charge state of a memory cell 205, which may result in errors when attempting to read the data stored at the memory cell 205. In some cases, corrective reading techniques may be used to adjust read voltages and improve RWB. However, corrective read operations may adversely impact read performance based on voltage strobing operations to word lines 265 adjacent along the z-direction (e.g., of adjacent pages 215) in order to adjust one or more read voltages, which may increase latency of the read operation and degrade efficiency of operations using the memory architecture 200.

In accordance with one or more techniques described herein, operations that implement the memory architecture 200 may be configured for corrective read operations with reduced strobe operations and reduced latency. For example, during a read operation of a first page 215, a memory system that includes the memory architecture 200 may be configured to perform one or more strobing operations to categorize each memory cell 205 coupled with a first word line 265 associated with the first page 215 into a range of stored charge (e.g., a bin) based on a written state (e.g., a charge state, a voltage state) of the memory cell 205. Information associated with the range of stored charge (e.g., an identifier, a bit value) may be stored for each memory cell 205 of the first page 215. During a subsequent read operation of a second page 215 (e.g., a page 215 adjacent to the first page 215 along the z-direction), the memory system may be configured to adjust read voltage offsets for reading memory cells 205 coupled with a second word line 265 associated with the second page 215 based on the categorization (e.g., the binning) of the memory cells 205 of the first page 215. Accordingly, the memory system may counteract the charge migration effects while reducing processing overhead, thus improving the accuracy of the read operation and maintaining or reducing latency associated with operations that implement the memory architecture 200.

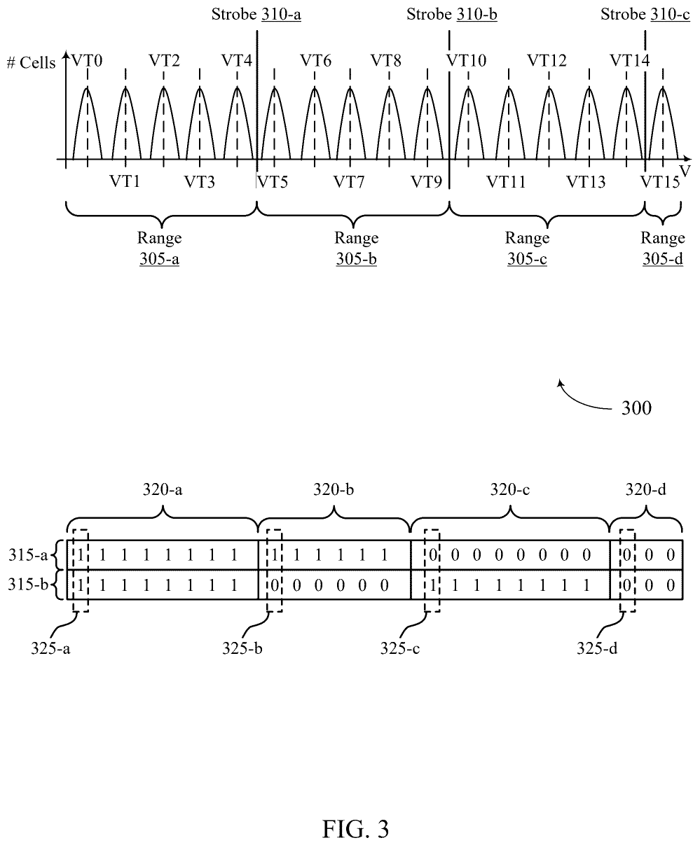

FIG. 3 shows an example of a VT distribution arrangement 300 that supports corrective read techniques for memory systems in accordance with examples as disclosed herein. The VT distribution arrangement 300 may illustrate a set of VT distributions for QLCs, where a QLC refers to a memory cell that is configured to store four bits of data using one of sixteen VT levels supported by the memory system (e.g., by a memory device 100). Each of the VT distributions may correspond to a respective QLC logic state, and may be associated with a respective voltage (e.g., a nominal voltage, a nominal threshold voltage, a target voltage, a nominal VT, an average VT), which may be a target threshold voltage written to memory cells for the respective QLC logic state (e.g., based on storing charge in a charge-trapping material of the memory cells). Thus, for the example of implementing QLCs, the VT distribution arrangement 300 may include sixteen VT distributions each associated with a respective voltage (e.g., sixteen nominal voltages, sixteen VT levels, labeled VT0 through VT15). Each nominal VT level may be associated with (e.g., correspond to, represent, store) a respective logic state (e.g., a multi-bit logic state, a 4-bit logic value for QLCs, a multi-bit value). For example, VT0 and its VT distribution may be associated with logic 1111, VT1 and its VT distribution may be associated with logic 1110, and so on. The VT distribution for a nominal VT level may be generally centered around the nominal VT level (e.g., the nominal VT level may be an average voltage for the VT distribution), and the VT distribution arrangement 300 may be illustrative of relative quantities of memory cells at various values of threshold voltage (e.g., among a population of memory cells, which may be written with a normalized distribution of, such as equal quantities of, the logic states).

Although described with reference to QLCs, the techniques described herein can be implemented using any type of threshold-voltage based memory cell, including SLCs that are configured to store a single bit in accordance with one of two threshold voltage levels (e.g., two nominal voltages), MLCs that are configured to store two bits in accordance with one of four threshold voltage levels (e.g., four nominal voltages), and TLCs that are configured to store three bits in accordance with one of eight threshold voltage levels (e.g., eight nominal voltages), and so on.

The VT distribution arrangement 300 may include the threshold voltages of memory cells in a physical page (e.g., a page 215), or other granularity of memory cells (e.g., a block 210), and the bits associated with the threshold voltages may represent data from multiple logical pages (e.g., multiple logical page configurations) associated with the physical page. For example, in the QLC context, a physical page may be associated with four stacked logical pages: a lower page (LP), an upper page (UP), an extra page (XP), and a top page (TP). In such an example, the least-significant bits of a physical page may represent the bits of the lower page, the second least-significant bits may represent the bits of the upper page, the second most-significant bits may represent the bits of the extra page, and the most-significant bits may represent the bits of the top page. An example for implementing bit values in accordance with such logical page configurations is provided in Table 1:

TABLE 1
Bit Values for QLC Logical Page Configuration

| | VT0 | VT1 | VT2 | VT3 | VT4 | VT5 | VT6 | VT7 | VT8 | VT9 | VT10 | VT11 | VT12 | VT13 | VT14 | VT15 |
|---|---|---|---|---|---|---|---|---|---|---|---|---|---|---|---|---|
| TP | 1 | 1 | 1 | 1 | 1 | 0 | 0 | 0 | 0 | 0 | 1 | 1 | 0 | 0 | 0 | 1 |
| XP | 1 | 1 | 0 | 0 | 0 | 0 | 0 | 0 | 1 | 1 | 1 | 1 | 1 | 1 | 0 | 0 |
| UP | 1 | 1 | 1 | 0 | 0 | 0 | 0 | 1 | 1 | 0 | 0 | 0 | 0 | 1 | 1 | 1 |
| LP | 1 | 0 | 0 | 0 | 1 | 1 | 0 | 0 | 0 | 0 | 0 | 1 | 1 | 1 | 1 | 1 |

To read the bits of a logical page (e.g., to distinguish between VT levels associated with a first bit value of the logical page and VT levels associated with a second bit value of the logical page, to determine a set or quantity of memory cells that activate), a memory system may be configured to apply a series of read voltages (e.g., a set of VTarget values) associated with that logical page. For instance, to read the bits of the lower page (e.g., to determine whether memory cells are storing an XXX0 logic state or an XXX1 logic state, where ‘X’ may be a 0 or 1 logic value not related to the lower page), the memory system may apply read voltages (e.g., values of VTarget, to a word line 165, to a word line 265) between VT0 and VT1, between VT3 and VT4, between VT5 and VT6, and between VT10 and VT11, and, for one or more of the read voltages, evaluate whether a threshold voltage of one or more memory cells is exceeded (e.g., evaluate whether a channel through the memory cells is activated, evaluate whether current flows through the memory cells). Similar techniques may be implemented with different sets of read voltages for reading bits of the upper page, the extra page, and the top page.

A set of memory cells (e.g., a page 215, a set associated with a word line 265) represented by the VT distribution arrangement 300 may be susceptible to various phenomenon, such as charge migration (e.g., lateral migration, vertical migration), that shift or otherwise alter VT for one or more of the memory cells. For instance, VT of a given memory cell may shift left or right due to the migration of charge between memory cells (e.g., memory cells of a given string 220, memory cells associated with contiguous charge trapping structures 120, memory cells associated with a contiguous NAND channel), particularly when adjacent memory cells store a different level of charge. In some cases (e.g., due to a relatively low RWB), charge migration may especially affect multiple-level memory cells such as QLC memory cells. Additionally, as tier pitch scaling decreases (e.g., as a dimension along the z-direction between pages 215 decreases), the impact of charge migration may become more pronounced. Accordingly, the read voltages used to read the memory cells may become inaccurate, which may reduce the ability of a memory system to reliably distinguish between logic values during read operations (resulting in read errors). The amount of VT drift experienced by a memory cell may vary with the target VT level (with higher target VT levels experiencing more VT drift).

In some cases, to compensate for VT changes caused by charge migration, corrective read mechanisms may be implemented, which may adjust one or more read voltage offsets for a given word line, WL_{N} (e.g., a word line 165, a word line 265). A corrective read operation may account for (e.g., determine, by way of strobing or scanning) the bit levels of memory cells on neighboring word lines (e.g., of neighboring pages 215), WL_{N+1} and WL_{N-1} (e.g., a charge state or voltage level of one or more adjacent memory cells), to determine the accurate read voltage offsets for WL_{N}. In some examples, one or more “strobes” may applied to the neighboring word lines (e.g., WL_{N+1} and WL_{N-1}) to evaluate stored charge of each memory cell of the neighboring word lines. A “strobe” (e.g., a strobe 310) may refer to a read voltage that is used to determine a state (e.g., a charge state, a threshold voltage state, a logic state) of a memory cell, and may be an example of a voltage VTarget applied to a word line (e.g., to control nodes 140). During a strobe, a specific voltage level (e.g., a read voltage or threshold voltage) may be applied to a set of memory cells (e.g., to a word line). A response of each cell to the applied voltage level may be measured to determine the state stored to each memory cell, which may support a categorization of how much each memory cell is likely to affect a threshold voltage of a neighboring memory cell (e.g., of a neighboring page 215).

After one or more strobe operations are performed for the neighboring word lines, a memory system may categorize each memory cell of the neighboring word lines into one of several ranges of stored charge (e.g., ranges 305), which may be referred to as “bins.” Each bin may, in some examples, be associated with multiple logic states (e.g., multiple VT distributions). Accordingly, one or more offsets may be applied to a set of read voltages used for reading a current word line (e.g., WL_{N}) based on the categorization (e.g., the bins) of memory cells of the neighboring word lines (e.g., WL_{N+1} and WL_{N-1}). The one or more offsets may thus improve a reliability of read operations by improving accuracy and improving a RWB (e.g., a voltage range within which a memory cell's stored data can be accurately read). However, corrective read operations may degrade read performance based on performing additional strobes of multiple neighboring word lines to determine the corresponding bit levels and based on pausing (e.g., interrupting) the read operation of the current word line.

As described herein, a memory system may be configured to implement an enhanced corrective read procedure to improve reliability of read operations (e.g., sequential read operations) and mitigate adverse effects to read performance. For example, the VT distributions may represent distributions of memory cells associated with a first word line (e.g., WL_{N-1}). A memory system may perform a first read operation for the first word line (e.g., a host page read of a previous word line) and may utilize information from the first read operation to determine (e.g., provide information associated with) the charge levels of the memory cells for first word line. For example, the memory system may apply one or more strobes 310 (e.g., a strobe 310-a, a strobe 310-b, a strobe 310-c) to categorize (e.g., perform binning of) each memory cell of the first word line into respective ranges 305 (e.g., four bins, corresponding to range 305-a, range 305-b, range 305-c, and range 305-d) based on the VT levels identified along the first word line. The respective ranges 305 may serve as a reference for adjustments (e.g., offsets) to a set of read voltages for a subsequent read operation (e.g., corrective read operations). That is, the memory system may adjust (e.g., shift, compensate, apply compensations to) one or more read voltages (e.g., read voltage levels) during a second read operation for a second word line (e.g., WL_{N}, a sequential or subsequent word line, a second page 215) based on the binning information from the first word line (e.g., WL_{N-1}, a first page 215).

In some examples, the strobe 310-a, the strobe 310-b, and the strobe 310-c may be associated with respective read voltages used for reading a given logical page (e.g., at least some of the read voltage values for reading a top page). The strobes 310 may be performed on a previous word line (e.g., WL_{N-1}) and may be utilized to categorize a potential leakage effect on memory cells of a current word line (e.g., WL_{N}, for a QLC example). In one example, the strobe 310-a may correspond to a first TP read voltage for a word line, the strobe 310-b may correspond to a second TP read voltage, and the strobe 310-c may correspond to a third TP read voltage (e.g., the strobes 310 may correspond to three out of four TP strobes). The strobes 310 may be used to establish one or more ranges 305 of stored charge. In the non-limiting example of FIG. 3 (e.g., a two-bit/one-side corrective read), the strobe 310-a, the strobe 310-b, and the strobe 310-c may create four ranges including range 305-a, range 305-b, range 305-c, and range 305-d. Other examples of strobes 310 are contemplated herein, including applying more or fewer strobes 310 to create more or fewer ranges 305, or applying strobes 310 at different voltage levels (e.g., strobes associated with LP read voltages, UP read voltages, XP read voltages, TP read voltages, other voltage levels, or any combination thereof) than shown, which may extend, narrow, or balance ranges 305. For example, the techniques for binning memory cells described herein may be extended for TLC device and the strobes 310 and the ranges 305 may be adjusted accordingly.

In some examples, read voltages associated with the TP logical page may be used based on being performed last among a set of logical page read operations (e.g., after each of the other logical pages). In some examples, data obtained during a read operation of a logical page may be stored (e.g., temporarily) in a cache (e.g., a primary data cache (PDC), one or more internal latches, NAND latches). Thus, if the read voltages for the TP are used, the memory system may perform binning the TP of a previous word line concurrently with a subsequent read operation for a next word line (e.g., without overwriting or otherwise coordinating a usage of the PDCs).

After applying the one or more strobes 310, the memory system may store one or more values indicative of range 305 of stored charge for each memory cell of the strobed word line (e.g., for each memory cell 205 of a page 215). For example, the memory system may utilize a cache 315-a (e.g., a first PDC) and a cache 315-b (e.g., a second PDC) to store the values. Each position (e.g., bit position) in the caches 315 may correspond to a given memory cell of the word line. In some examples, the memory system may utilize one or more bits from each cache 315 (e.g., bits in a same position of the respective caches 315) to store a respective value for a memory cell. For example, the bits 325-a may correspond to a first memory cell, the bits 325-b may correspond to a second memory cell, the bits 325-c may correspond to a third memory cell, and the bits 325-d may correspond to a fourth memory cell, and so on.

The values of the bits (e.g., bits 325) may be indicative of a range 305 of stored charge to which the given memory cell is associated with. For example, each pair of bits within a group 320-a may indicate a first value (e.g., “11”) corresponding to a first range 305 (e.g., range 305-a), each pair of bits with in a group 320-b may indicate a second value (e.g., “10”) corresponding to a second range 305 (e.g., range 305-b), each pair of bits with in a group 320-c may indicate a third value (e.g., “01”) corresponding to a third range 305 (e.g., range 305-c), and each pair of bits with in a group 320-d may indicate a fourth value (e.g., “00”) corresponding to a fourth range 305 (e.g., range 305-d).

Accordingly, during a read operation for a subsequent word line, a memory system may utilize the information stored in the caches 315 to adjust a set of read voltages. For example, the bits 325-a may correspond to a first memory cell of a previous word line. During a read operation of a current word line, the memory system may utilize the value indicated by the bits 325-a to adjust a read voltage for a second memory cell of the current word line that corresponds to (e.g., associated with a same NAND channel, associated with a same string 220, an adjacent memory cell, a memory cell that shares a same charge storing layer or charge trapping structure 120) the first memory cell of the previous word line.

In some examples, a memory system may read data from a set of multiple first memory cells (e.g., NAND memory cells) associated with a first word line (e.g., WL_{N-1}). The memory system may read the first memory cells in accordance with a set of multiple logical page configurations (e.g., LP, UP, XP, TP). The memory system may determine, for each first memory cell of the set, a respective range 305 (e.g., a bin) of stored charge corresponding to a respective written state (e.g., charge state, VT state, logic state) of each first memory cell. In some examples, determining the respective ranges 305 may be based on reading data from the set first memory cells. In some examples, determining the ranges 305 of each first memory cell may be associated with reading the first memory cells in accordance with one of the set of multiple logical page configurations (e.g., a TP configuration, or another logical page).

In some examples, the memory system may determine the respective range 305 of stored charge from a set of multiple ranges 305 (e.g., range 305-a, range 305-b, range 305-c, range 305-d) of stored charge that correspond to a logical page configuration of a set of multiple logical page configurations associated with the first word line. In some examples, at least some of (e.g., more than one of, all of) the ranges 305 may be associated with a respective logic state in accordance with the logical page configuration. For example, range 305-a may be associated with a TP logic 1, range 305-b may be associated with a TP logic 0, and range 305-d may be associated with a TP logic 1. In another example, ranges 305 may be associated with respective bit values of an XP logical page configuration, which may implement each of the three read voltages that divide the VT ranges of a given bit value of the XP logical page configuration (e.g., for which each of four ranges 305 corresponds to a given logic state, 0 or 1, in accordance with the XP configuration or illustrative VT levels thereof, which may be implemented in another logical page configuration, such as a TP). In some examples, the memory system may read the second memory cells in accordance with one or more of the set of multiple logical page configurations, and each of the one or more logical page configurations may be associated with a respective subset of the respective set of one or more read voltages (e.g., used to read the second word line).

In some examples, the memory system may read a set of multiple second memory cells (e.g., NAND memory cells) associated with a second word line (e.g., WL_{N}) different than the first word line. The first word line and the second word line, in some examples, may be physically sequential (e.g., along the z-direction) among a set of word lines. That is, the memory system may read the first and second word lines based on a sequential read operation associated with the first word line and the second word line. In some examples, reading the second memory cells may include biasing each second memory cell with a respective set of one or more read voltages. The one or more read voltages may be based on the respective ranges 305 of stored charge of a respective first memory cell of the set of first memory cells that corresponds to a respective second memory cell. In some examples, a respective second memory cell and a respective first memory cell may corresponds to each other based on sharing a contiguous semiconductor channel material, or sharing a contiguous charge storing material between respective gate nodes and respective semiconductor channel portions, or both.

In some examples, reading data from the set first memory cells may be associated with one or more second read voltages that are different than the respective sets of one or more read voltages (e.g., used for reading the second word line). That is, at least one voltage level used for reading the second set of memory cells may be adjusted (e.g., shifted) relative to its corresponding read voltage used for reading the first set of memory cells. For example, the second word line may be biased with multiple sets of VTarget values, each set having an adjustment made based on a respective range 305 that is populated by one or more memory cells along the first word line. In some examples, reading the second memory cells may include biasing the second word line with each voltage of a first respective set of one or more read voltages corresponding to a second memory cell (e.g., a first set of VTarget values being adjusted based on the second memory cell being in a first range 305). The reading may further include biasing the second word line with each voltage of a second respective set of one or more read voltages corresponding to another second memory cell (e.g., a different memory cell along the second word line), and the second respective set may be different than the first respective set (e.g., a second set of VTarget values being adjusted based on the other second memory cell being in a second range 305). That is, each memory cell of a word line may be associated with a unique set of read voltages (e.g., based on the binning).

In some examples, the memory system may store one or more values indicative of the respective range 305 of stored charge for each first memory cell to one or more caches 315 (e.g., the cache 315-a and the cache 315-b). That is, the respective set of one or more read voltages for biasing the second memory cells may be based on the one or more values stored the one or more caches 315. In some examples, the memory system may determine, for each second memory cell, a respective voltage level for each read voltage based on the value stored to the one or more cache 315 for a first memory cell that corresponds to each second memory cell. In some examples, the memory system may output (e.g., transmit) data associated with the second word line based on reading (e.g., the corrective reading) the second word line.

Accordingly, by implementing one or more techniques described herein a memory system may mitigate charge migration effects between neighboring memory cells (e.g., by enhancing a RWB of the memory cells). Additionally, a frequency at which error handling mechanisms are initiated by the memory system may be reduced (e.g., reduced trigger rates), thus mitigating performance degradation associated with error handling. The techniques herein may further apply to scenarios of sequential read operations after a long power-off period and out-of-the-box experiences. Moreover, the techniques herein leverage corrective read schemes and internal latches (e.g., NAND latches), thus resulting in improved RWB without introducing additional cost or complexity. The one or more techniques herein may further apply for future memory systems, such as NAND memory systems with significantly reduced tier pitch scaling. Accordingly, the memory system may operate with improved read reliability, reduced latency, improve response times, and otherwise improve user experience, among other benefits.

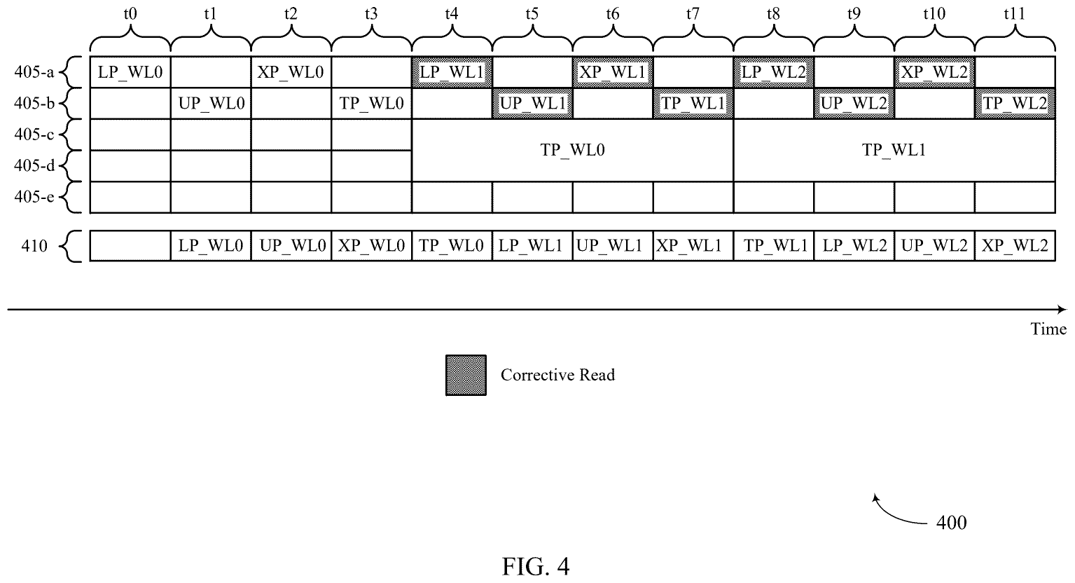

FIG. 4 shows an example of a timing diagram 400 that supports corrective read techniques for memory systems in accordance with examples as disclosed herein. The timing diagram 400 may illustrate operations performed by a memory system, which may be an example of or include corresponding devices herein, including as described with reference to FIGS. 1 through 3. Each row of the timing diagram 400 may represent a cache 405 (e.g., a PDC, a set of latches internal to a memory system). Each column may represent a respective duration (e.g., t0, t1, t2, and so on). Another row of the timing diagram 400 may represent a secondary cache 410 (e.g., a secondary data cache (SDC), another set of latches internal to a memory system). In some examples, a memory system may support various configurations of caches 405 and secondary caches 410, including any respective quantity of caches 405 and secondary caches 410.

During a given duration, information associated with a respective word line (WL) operation (e.g., a read operation on a page 215, a read operation in accordance with a logical page configuration) may be stored (e.g., written, transferred) to a given cache 405 and/or secondary cache 410. In some examples, LP_WL0 may indicate an LP read on WL0, UP_WL0 may indicate a UP read on WL0, XP_WL1 may indicate an XP read on WL1, TP_WL2 may indicate a TP read on WL2, and so on. For example, at t0, data associated with the LP of one or more memory cells of WL0 (e.g., LP-WL0) may be stored to the cache 405-a, at t1, data associated with the UP of one or more memory cells of WL0 may be stored to the cache 405-b (e.g., UP_WL0) and the information associated with LP_WL0 may be stored to the secondary cache 410, and so on. Some operations may be associated with a corrective read operation (e.g., as shown in FIG. 4). For example, at t4, data associated with the LP of W1 may be read in accordance with a corrective read (e.g., using TP_WL0 information stored in cache 405-c and cache 405-d) may be stored to the cache 405-a.

In accordance with the timing diagram 400, t0 through t3 may illustrate example read operations for WL0 (e.g., in accordance with four logical page configurations). In some examples, at t0, the memory system may read the LP of WL0 into a first cache 405 (e.g., cache 405-a, an available cache). At t1, the memory system may read the UP of WL0 into a second cache 405 (e.g., cache 405-b, another available cache such as the cache 405-e) and may transfer the LP data of WL0 to the secondary cache 410. At t2, the memory system may read the XP of WL0 into the first cache 405 (e.g., cache 405-a) and may transfer the UP data of WL0 to the secondary cache 410. At t3, the memory system may read the TP of WL0 into the second cache 405 (e.g., cache 405-b) and may transfer the XP data of WL0 to the secondary cache 410. In some examples, based on the strobes (e.g., three strobes, strobes 310) of the TP data for WL0, the memory system may group the memory cells of the WL0 into multiple (e.g., four) bins (e.g., associated with ranges 305) and may store the binning information (e.g., TP_WL0) in a third cache 405 (e.g., a cache 405-c, a cache 315-a, an available cache) and a fourth cache 405 (e.g., a cache 405-d, a cache 315-b, an available cache).

Further, t4 through t7 may illustrate example read operations for WL1 (e.g., in accordance with the four logical page configurations). The read operations for WL1 may include corrective read operations that utilize the binning information stored in cache 405-c and cache 405-d (e.g., TP_WL0). In some examples, at t4, the memory system may perform a corrective read of the LP of WL1 into the first cache 405 and may also transfer the TP data of WL0 to the secondary cache 410. At t5, the memory system may perform a corrective read of the UP of WL1 into the second cache 405 and may transfer the LP data of WL1 to the secondary cache 410. At t6, the memory system may perform a corrective read of the XP of WL1 into the first cache 405 and may transfer the UP data of WL1 to the secondary cache 410. At t7, the memory system may perform a corrective read of the TP of WL1 into the second cache 405 and may transfer the XP data of WL1 to the secondary cache 410. In some examples, based on the strobes (e.g., three strobes, strobes 310) of the TP data for WL1, the memory system may group the memory cells of the WL1 into multiple (e.g., four) bins (e.g., associated with ranges 305) and may store the binning information (e.g., TP_WL1) in the third cache 405 and the fourth cache 405.

A similar set of operations may be performed for each word line of the memory system. For example, t8 through t11 may illustrate example read operations for WL2, which may include corrective read operations that utilize the binning information stored in cache 405-c and cache 405-d (e.g., TP_WL1). Thus, one or more caches 405 (e.g., PDCs, NAND internal latches) may serve as a temporary storage for data from a previous word line, which may then be utilized for a corrective read. Additionally, if any other available storage location within the memory system is available, such locations may also be leveraged for the describes techniques. Accordingly, the benefits associated with the one or more techniques described herein may be achieved with little or no additional overhead in terms of hardware implementation or resource consumption.

Thus, in accordance with these and other techniques, operations of a memory system (e.g., of a memory device 100, operations that implement a memory architecture 200) may be configured for corrective read operations with reduced strobe operations and reduced latency. For example, during a first read operation (e.g., of a first word line 265, of a first page 215), a memory system may be configured to perform one or more strobing operations to categorize each memory cell 205 coupled with a first word line 265 into a range 305 based on a written state (e.g., a charge state, a voltage state) of the memory cell 205. Information associated with the range 305 may be stored for each memory cell 205 along the first word line 265. During a subsequent read operation (e.g., of a second word line 265, of a second page 215), the memory system may be configured to adjust read voltage offsets for reading memory cells 205 coupled with a second word line 265 based on the categorization of the memory cells 205 along the first word line 265 into ranges 305 (e.g., to make adjustments based on memory cells that are adjacent along the z-direction, or share a contiguous channel or charge-trapping material). Such techniques may implement caches, such as caches 405 and secondary cache(s) 410 that are already implemented for read operations, and, in some examples (e.g., for sequential read operations), may perform such binning and read voltage adjustment without additional strobe operations not part of a prior read operation (e.g., leveraging read voltages already applied in a read operation of a sequential page 215). Accordingly, the memory system may counteract the charge migration effects while reducing processing overhead, thus improving the accuracy of the read operation and maintaining or reducing latency compared with other techniques.

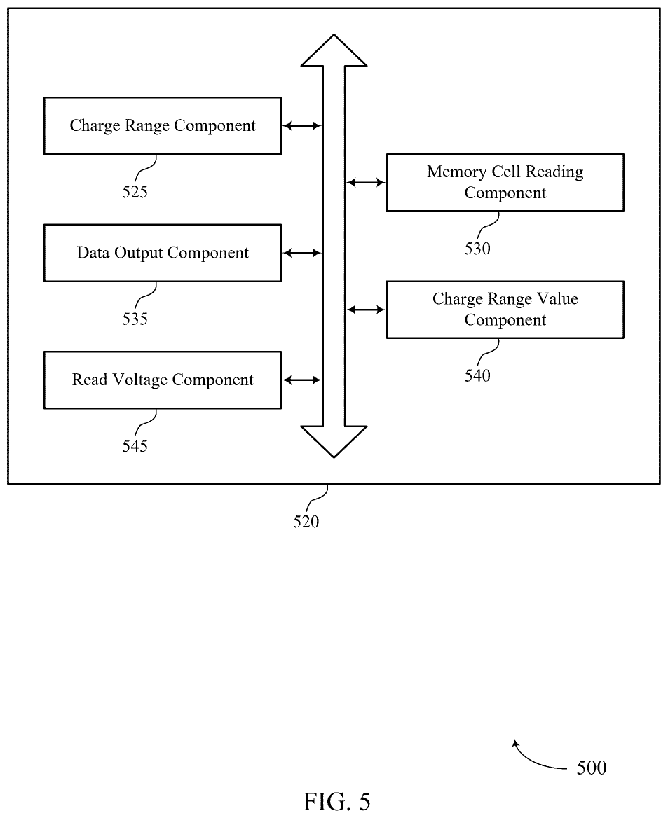

FIG. 5 shows a block diagram 500 of a memory system 520 that supports corrective read techniques for memory systems in accordance with examples as disclosed herein. The memory system 520 may be an example of aspects of a memory system as described with reference to FIGS. 1 through 4. For example, the memory system 520 may be an example of a memory device 100, or may include one or more memory devices 100 (e.g., in an mNAND implementation), which may be coupled with components of (e.g., processing circuitry of, a memory system controller of) the memory system 520 to support one or of the operations described herein. The memory system 520, or various components thereof, may be an example of means for performing various aspects of corrective read techniques for memory systems as described herein. For example, the memory system 520 may include a charge range component 525, a memory cell reading component 530, a data output component 535, a charge range value component 540, a read voltage component 545, or any combination thereof. Each of these components, or components of subcomponents thereof (e.g., one or more processors, one or more memories), may communicate, directly or indirectly, with one another (e.g., via one or more buses).

The charge range component 525 may be configured as or otherwise support a means for determining, for each first memory cell of a plurality of first memory cells (e.g., memory cells 105, memory cells 205) associated with a first word line (e.g., of word lines 165, of word lines 265), a respective range of stored charge corresponding to a respective written state of the each first memory cell. The memory cell reading component 530 may be configured as or otherwise support a means for reading a plurality of second memory cells associated with a second word line different than the first word line, the reading including biasing each second memory cell of the plurality of second memory cells with a respective set of one or more read voltages that is based at least in part on the respective range of stored charge of a first memory cell of the plurality of first memory cells that corresponds to the each second memory cell. The data output component 535 may be configured as or otherwise support a means for outputting data associated with the second word line based at least in part on the reading of the plurality of second memory cells.

In some examples, the memory cell reading component 530 may be configured as or otherwise support a means for reading data from the plurality of first memory cells, where determining the respective range of stored charge corresponding to the respective written state of the each first memory cell is based at least in part on the reading data from the plurality of first memory cells.

In some examples, the reading data from the plurality of first memory cells and the reading of the plurality of second memory cells are based at least in part on a sequential read operation associated with the first word line and the second word line.

In some examples, the reading data from the plurality of first memory cells is associated with one or more second read voltages that are different than the respective sets of one or more read voltages.

In some examples, the reading data from the plurality of first memory cells includes reading the plurality of first memory cells in accordance with a plurality of logical page configurations. In some examples, the determining the respective range of stored charge corresponding to the respective written state of the each first memory cell is associated with the reading in accordance with one of the plurality of logical page configurations.

In some examples, to support reading the plurality of second memory cells, the memory cell reading component 530 may be configured as or otherwise support a means for biasing the second word line with each voltage of a first respective set of one or more read voltages corresponding to one of the plurality of second memory cells. In some examples, to support reading the plurality of second memory cells, the memory cell reading component 530 may be configured as or otherwise support a means for biasing the second word line with each voltage of a second respective set of one or more read voltages corresponding to another of the plurality of second memory cells, the second respective set being different than the first respective set.

In some examples, the charge range value component 540 may be configured as or otherwise support a means for storing a value indicative of the respective range of stored charge for the each first memory cell to a cache, where the respective set of one or more read voltages for biasing the each second memory cell is based at least in part on the value stored the cache.

In some examples, the read voltage component 545 may be configured as or otherwise support a means for determining, for the each second memory cell, a respective voltage level for each of the respective set of one or more read voltages based at least in part on the value stored to the cache for the first memory cell that corresponds to the each second memory cell.

In some examples, to support determining the respective range of stored charge for the each first memory cell, the charge range component 525 may be configured as or otherwise support a means for determining the respective range of stored charge from a plurality of ranges of stored charge that correspond to a logical page configuration of a plurality of logical page configurations associated with the first word line, each of the plurality of ranges associated with a respective logic state in accordance with the logical page configuration.

In some examples, to support reading the plurality of second memory cells, the memory cell reading component 530 may be configured as or otherwise support a means for reading the plurality of second memory cells in accordance with one or more of the plurality of logical page configurations, each of the one or more logical page configurations associated with a respective subset of the respective set of one or more read voltages.

In some examples, the each second memory cell and the first memory cell that corresponds to the each second memory cell share a contiguous semiconductor channel material (e.g., along a string 220), or share a contiguous charge storing material between respective gate nodes and respective semiconductor channel portions (e.g., of a string 220), or both.

In some examples, the first word line and the second word line are physically sequential among a set of word lines (e.g., along the z-direction, along a direction from a substrate, along a level direction, along a string 220).

In some examples, the plurality of first memory cells and the plurality of second memory cells are NAND memory cells.

In some examples, the described functionality of the memory system 520, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 520, or various components thereof, may be implemented at least in part by instructions (e.g., stored in memory, non-transitory computer-readable medium) executable by such at least one processor.

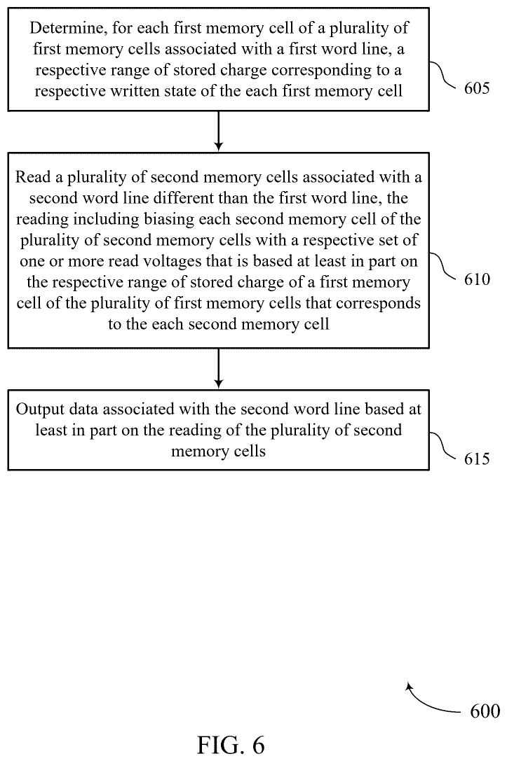

FIG. 6 shows a flowchart illustrating a method 600 that supports corrective read techniques for memory systems in accordance with examples as disclosed herein. The operations of method 600 may be implemented by a memory system or its components as described herein. For example, the operations of method 600 may be performed by a memory system as described with reference to FIGS. 1 through 5 (e.g., by a memory device 100, by a memory system that includes one or more memory devices 100). In some examples, a memory system may execute a set of instructions to control the functional elements of the device to perform the described functions. Additionally, or alternatively, the memory system may perform aspects of the described functions using special-purpose hardware.

At 605, the method may include determining, for each first memory cell of a plurality of first memory cells (e.g., memory cells 105, memory cells 205) associated with a first word line (e.g., of word lines 165, of word lines 265), a respective range of stored charge corresponding to a respective written state of the each first memory cell. In some examples, aspects of the operations of 605 may be performed by a charge range component 525 as described with reference to FIG. 5.

At 610, the method may include reading a plurality of second memory cells associated with a second word line different than the first word line, the reading including biasing each second memory cell of the plurality of second memory cells with a respective set of one or more read voltages that is based at least in part on the respective range of stored charge of a first memory cell of the plurality of first memory cells that corresponds to the each second memory cell. In some examples, aspects of the operations of 610 may be performed by a memory cell reading component 530 as described with reference to FIG. 5.

At 615, the method may include outputting data associated with the second word line based at least in part on the reading of the plurality of second memory cells. In some examples, aspects of the operations of 615 may be performed by a data output component 535 as described with reference to FIG. 5.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:
Aspect 1: A method, apparatus, or non-transitory computer-readable medium including operations, features, circuitry, logic, means, or instructions, or any combination thereof for determining, for each first memory cell of a plurality of first memory cells associated with a first word line, a respective range of stored charge corresponding to a respective written state of the each first memory cell; reading a plurality of second memory cells associated with a second word line different than the first word line, the reading including biasing each second memory cell of the plurality of second memory cells with a respective set of one or more read voltages that is based at least in part on the respective range of stored charge of a first memory cell of the plurality of first memory cells that corresponds to the each second memory cell; and outputting data associated with the second word line based at least in part on the reading of the plurality of second memory cells.
Aspect 2: The method, apparatus, or non-transitory computer-readable medium of aspect 1, further including operations, features, circuitry, logic, means, or instructions, or any combination thereof for reading data from the plurality of first memory cells, where determining the respective range of stored charge corresponding to the respective written state of the each first memory cell is based at least in part on the reading data from the plurality of first memory cells.
Aspect 3: The method, apparatus, or non-transitory computer-readable medium of aspect 2, where the reading data from the plurality of first memory cells and the reading of the plurality of second memory cells are based at least in part on a sequential read operation associated with the first word line and the second word line.
Aspect 4: The method, apparatus, or non-transitory computer-readable medium of any of aspects 2 through 3, where the reading data from the plurality of first memory cells is associated with one or more second read voltages that are different than the respective sets of one or more read voltages.
Aspect 5: The method, apparatus, or non-transitory computer-readable medium of any of aspects 2 through 4, where the reading data from the plurality of first memory cells includes reading the plurality of first memory cells in accordance with a plurality of logical page configurations and the determining the respective range of stored charge corresponding to the respective written state of the each first memory cell is associated with the reading in accordance with one of the plurality of logical page configurations.
Aspect 6: The method, apparatus, or non-transitory computer-readable medium of any of aspects 1 through 5, where reading the plurality of second memory cells includes operations, features, circuitry, logic, means, or instructions, or any combination thereof for biasing the second word line with each voltage of a first respective set of one or more read voltages corresponding to one of the plurality of second memory cells and biasing the second word line with each voltage of a second respective set of one or more read voltages corresponding to another of the plurality of second memory cells, the second respective set being different than the first respective set.
Aspect 7: The method, apparatus, or non-transitory computer-readable medium of any of aspects 1 through 6, further including operations, features, circuitry, logic, means, or instructions, or any combination thereof for storing a value indicative of the respective range of stored charge for the each first memory cell to a cache, where the respective set of one or more read voltages for biasing the each second memory cell is based at least in part on the value stored the cache.
Aspect 8: The method, apparatus, or non-transitory computer-readable medium of aspect 7, further including operations, features, circuitry, logic, means, or instructions, or any combination thereof for determining, for the each second memory cell, a respective voltage level for each of the respective set of one or more read voltages based at least in part on the value stored to the cache for the first memory cell that corresponds to the each second memory cell.
Aspect 9: The method, apparatus, or non-transitory computer-readable medium of any of aspects 1 through 8, where determining the respective range of stored charge for the each first memory cell includes operations, features, circuitry, logic, means, or instructions, or any combination thereof for determining the respective range of stored charge from a plurality of ranges of stored charge that correspond to a logical page configuration of a plurality of logical page configurations associated with the first word line, each of the plurality of ranges associated with a respective logic state in accordance with the logical page configuration.
Aspect 10: The method, apparatus, or non-transitory computer-readable medium of aspect 9, where reading the plurality of second memory cells further includes operations, features, circuitry, logic, means, or instructions, or any combination thereof for reading the plurality of second memory cells in accordance with one or more of the plurality of logical page configurations, each of the one or more logical page configurations associated with a respective subset of the respective set of one or more read voltages.
Aspect 11: The method, apparatus, or non-transitory computer-readable medium of any of aspects 1 through 10, where the each second memory cell and the first memory cell that corresponds to the each second memory cell share a contiguous semiconductor channel material, or share a contiguous charge storing material between respective gate nodes and respective semiconductor channel portions, or both.
Aspect 12: The method, apparatus, or non-transitory computer-readable medium of any of aspects 1 through 11, where the first word line and the second word line are physically sequential among a set of word lines.
Aspect 13: The method, apparatus, or non-transitory computer-readable medium of any of aspects 1 through 12, where the plurality of first memory cells and the plurality of second memory cells are NAND memory cells.

It should be noted that the described methods include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed and second condition or action may occur directly as a result of the previous condition or action occurring independent of whether other conditions or actions occur. In some examples, a first condition or action may be performed and second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively, (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more memory devices; and
processing circuitry coupled with the one or more memory devices and configured to cause the memory system to:
determine, for each first memory cell of a plurality of first memory cells associated with a first word line, a respective range of stored charge corresponding to a respective written state of each first memory cell;
read a plurality of second memory cells associated with a second word line different than the first word line, the reading comprising biasing each second memory cell of the plurality of second memory cells with a respective set of one or more read voltages that is based at least in part on the respective range of stored charge of a first memory cell of the plurality of first memory cells that corresponds to each second memory cell; and
output data associated with the second word line based at least in part on the reading of the plurality of second memory cells.

2. The memory system of claim 1, wherein the processing circuitry is further configured to cause the memory system to:
read data from the plurality of first memory cells, wherein determining the respective range of stored charge corresponding to the respective written state of each first memory cell is based at least in part on the reading of the data from the plurality of first memory cells.

3. The memory system of claim 2, wherein the reading of the data from the plurality of first memory cells and the reading of the plurality of second memory cells are based at least in part on a sequential read operation associated with the first word line and the second word line.

4. The memory system of claim 2, wherein the reading of the data from the plurality of first memory cells is associated with one or more second read voltages that are different than the respective sets of one or more read voltages.

5. The memory system of claim 2, wherein:
the reading of the data from the plurality of first memory cells comprises reading the plurality of first memory cells in accordance with a plurality of logical page configurations; and
the determining the respective range of stored charge corresponding to the respective written state of each first memory cell is associated with the reading in accordance with one of the plurality of logical page configurations.

6. The memory system of claim 1, wherein reading the plurality of second memory cells comprises the processing circuitry configured to cause the memory system to:
bias the second word line with each voltage of a first respective set of one or more read voltages corresponding to one of the plurality of second memory cells; and
bias the second word line with each voltage of a second respective set of one or more read voltages corresponding to another of the plurality of second memory cells, the second respective set being different than the first respective set.

7. The memory system of claim 1, wherein the processing circuitry is further configured to cause the memory system to:
store a value indicative of the respective range of stored charge for each first memory cell to a cache, wherein the respective set of one or more read voltages for biasing each second memory cell is based at least in part on the value stored the cache.

8. The memory system of claim 7, wherein the processing circuitry is further configured to cause the memory system to:
determine, for each second memory cell, a respective voltage level for each of the respective set of one or more read voltages based at least in part on the value stored to the cache for the first memory cell that corresponds to each second memory cell.

9. The memory system of claim 1, wherein determining the respective range of stored charge for each first memory cell comprises the processing circuitry configured to cause the memory system to:
determine the respective range of stored charge from a plurality of ranges of stored charge that correspond to a logical page configuration of a plurality of logical page configurations associated with the first word line, each of the plurality of ranges associated with a respective logic state in accordance with the logical page configuration.

10. The memory system of claim 9, wherein reading the plurality of second memory cells further comprises the processing circuitry configured to cause the memory system to:
read the plurality of second memory cells in accordance with one or more logical page configurations of the plurality of logical page configurations, each of the one or more logical page configurations associated with a respective subset of the respective set of one or more read voltages.

11. The memory system of claim 1, wherein each second memory cell and the first memory cell that corresponds to each second memory cell share a contiguous semiconductor channel material, or share a contiguous charge storing material between respective gate nodes and respective semiconductor channel portions, or both.

12. The memory system of claim 1, wherein the first word line and the second word line are physically sequential among a set of word lines.

13. The memory system of claim 1, wherein:
the plurality of first memory cells and the plurality of second memory cells are NAND memory cells.

14. A method at a memory system, comprising:
determining, for each first memory cell of a plurality of first memory cells associated with a first word line, a respective range of stored charge corresponding to a respective written state of each first memory cell;
reading a plurality of second memory cells associated with a second word line different than the first word line, the reading comprising biasing each second memory cell of the plurality of second memory cells with a respective set of one or more read voltages that is based at least in part on the respective range of stored charge of a first memory cell of the plurality of first memory cells that corresponds to each second memory cell; and
outputting data associated with the second word line based at least in part on the reading of the plurality of second memory cells.

15. The method of claim 14, further comprising:
reading data from the plurality of first memory cells, wherein determining the respective range of stored charge corresponding to the respective written state of each first memory cell is based at least in part on the reading of the data from the plurality of first memory cells.

16. The method of claim 15, wherein the reading of the data from the plurality of first memory cells and the reading of the plurality of second memory cells are based at least in part on a sequential read operation associated with the first word line and the second word line.

17. The method of claim 15, wherein the reading of the data from the plurality of first memory cells is associated with one or more second read voltages that are different than the respective sets of one or more read voltages.

18. The method of claim 15, wherein:
the reading of the data from the plurality of first memory cells comprises reading the plurality of first memory cells in accordance with a plurality of logical page configurations; and
the determining the respective range of stored charge corresponding to the respective written state of each first memory cell is associated with the reading in accordance with one of the plurality of logical page configurations.

19. A non-transitory computer-readable medium storing code, the code comprising instructions executable by one or more processors to:
determine, for each first memory cell of a plurality of first memory cells associated with a first word line, a respective range of stored charge corresponding to a respective written state of each first memory cell;
read a plurality of second memory cells associated with a second word line different than the first word line, the reading comprising biasing each second memory cell of the plurality of second memory cells with a respective set of one or more read voltages that is based at least in part on the respective range of stored charge of a first memory cell of the plurality of first memory cells that corresponds to each second memory cell; and
output data associated with the second word line based at least in part on the reading of the plurality of second memory cells.

20. The non-transitory computer-readable medium of claim 19, wherein the instructions are further executable by the one or more processors to:
read data from the plurality of first memory cells, wherein determining the respective range of stored charge corresponding to the respective written state of each first memory cell is based at least in part on the reading of the data from the plurality of first memory cells.
